(19) United States
(12) Patent Application Publication
(10) Pub. No.: US 2022/0199782 A1
(43) Pub. Date: Jun. 23, 2022

(54) INTEGRATED ELECTRONICS ON THE ALUMINUM NITRIDE PLATFORM

(71) Applicant: CORNELL UNIVERSITY, Ithaca, NY (US)

(72) Inventors: Austin Hickman, Ithaca, NY (US); Reet Chaudhuri, Ithaca, NY (US); James C. M. Hwang, Ithaca, NY (US); Huili Grace Xing, Ithaca, NY (US); Debdeep Jena, Ithaca, NY (US)

(73) Assignee: Cornell University, Ithaca, NY (US)

(21) Appl. No.: 17/554,511

(22) Filed: Dec. 17, 2021

Related U.S. Application Data
(60) Provisional application No. 63/128,044, filed on Dec. 19, 2020.

(51) Int. Cl. H01L 29/20; H01L 29/778; H01L 23/66; H01L 23/373; H03F 3/195

(52) U.S. Cl. CPC H01L 29/2003; H01L 29/7787; H01L 23/66; H01L 23/3736; H03F 2200/451; H01L 2223/6616; H01L 2223/6627; H01L 2223/6683; H03F 3/195

(57) ABSTRACT

Gallium nitride high-electron-mobility transistors (GaN HEMTs) are at a point of rapid growth in defense (radar, SATCOM) and commercial (5G and beyond) industries. This growth also comes at a point at which the standard GaN heterostructures remain unoptimized for maximum performance. For this reason, the shift to the aluminum nitride (AlN) platform is disclosed. AlN allows for smarter, highly-scaled heterostructure design that improves the output power and thermal management of GaN amplifiers. Beyond improvements over the incumbent amplifier technology, AlN allows for a level of integration previously unachievable with GaN electronics. State-of-the-art high-current p-channel FETs, mature filter technology, and advanced waveguides, all monolithically integrated with an AlN/GaN/AlN HEMT, is made possible with aluminum nitride. It is on this AlN platform that nitride electronics may maximize their full high-power, highspeed potential for mm-wave communication and high-power logic applications.

### CROSS REFERENCE TO RELATED APPLICATIONS

This application claims priority to U.S. Provisional Patent Application Ser. No. 63/128,044, filed Dec. 19, 2020, entitled INTEGRATED ELECTRONICS ON THE ALUMINUM NITRIDE PLATFORM, which is incorporated herein by reference in its entirety and for all purposes.

### BACKGROUND

These teachings relate generally to platforms for III-N devices, and, more particularly, to Aluminum nitride as a platforms for III-N devices.

As the wireless communication networks that connect our world push to ever-higher frequencies, the performance demand on radio frequency (RF) transistor technology amplifies. The need for higher power, frequency, and efficiency should also comply with the necessity for low cost and small footprint. This strain of competing interests is perhaps highlighted best in the millimeter-wave (mm-wave) frequency range. The mm-wave spectrum is at a point of rapid growth and expansion in commercial and military application spaces. This is due to mm-wave's capability for high directionality, and its short wavelength which translates to faster data transmission (>1 Gbit/s) and higher resolution imaging than other radio waves.

Many material platforms are vying for market share in this emerging frequency range. Silicon, bolstered by its maturity and cost-effective scale, has produced output powers up to 1 W in the sub-6 GHz regime with silicon lateral-diffusion metal-oxide-semiconductor (LDMOS)technology, but struggles at higher frequencies. Successful operation in the mm-wave frequency range has been achieved by gallium arsenide high-electron-mobility transistors (GaAs HEMTs), silicon germanium heterojunction bipolar transistors (SiGe HBTs), and indium phosphide HBTs, albeit at relatively low power levels. To achieve high-power and mm-wave operation simultaneously, focus has turned to gallium nitride (GaN) HEMTs. The relevant material properties of each material platform are shown in Table 1. GaN's combination of high saturation velocity and wide bandgap enable it's high-power, high-frequency performance, and establish it as the premier material for future mm-wave electronics.

TABLE 1
Physical Properties of Relevant Materials
for high-power RF transistors.

| | E_{gap} | E_{C} | μ | νₛₐₜ | σₜₕₑᵣₘ |
|---|---|---|---|---|---|
| Material | (eV) | (MV/cm) | (cm²/V · s) | (×10⁷cm/s) | (W/cm · K) |
| Silicon | 1.12 | 0.3 | 1440 | 1.0 | 1.3 |
| InP | 1.34 | 0.5 | 5400 | 3.9 | 0.68 |
| GaAs | 1.42 | 0.52 | 9400 | 0.9 | 0.55 |
| GaN | 3.4 | 3 | 1400 | 2.4 | 2.5 |
| AlN | 6.2 | 15 | 450 | 1.4 | 3.4 |
| SiC | 3.3 | 3 | 900 | 0.8 | 4.2 |

In the past two decades, GaN HEMTs have routinely demonstrated record high power density performance across the GHz frequency range. Initial reports of GaN HEMT performance focused on the conventional AlGaN/GaN heterostructures with an emphasis on electric field-shaping metal plates, which allow GaN's breakdown performance to further exceed all other competitive platforms.

Among the remarkable power densities demonstrated were 40 W/mm and 30 W/mm at 4 and 8 GHz, respectively. AlGaN/GaN HEMTs have also shown 10.5 W/mm at 40 GHz (higher frequency). In an effort to scale for higher frequencies and account for short-channel effects (SCEs), other heterostructures were introduced, such as InAlN-barrier and InAlGaN-barrier HEMTs, which has demonstrated over 1 W/mm at 94 GHz and 3 W/mm at 96 GHz, respectively. Current state-of-the-art performance has been achieved using N-polar GaN HEMTs. By incorporating a thick GaN cap layer, N-polar HEMTs have significantly reduced device dispersion and maintain output powers above 8 W/mm at up to 94 GHz.

As has historically been the case with developing semiconductor technologies, the laboratory achievements of GaN amplifiers made its first major application appearances in the defense industry. In 2018, Northrup Grumman supplied the first GaN-based ground/air radar system to the U.S. Marine Corps. The Space Fence, a radar network used to track objects in Earth's orbit made possible with GaN amplifiers, was enabled by Lockheed Martin, and declared operational by the U.S. Space Force earlier this year. GaN is also emerging in commercial spaces, first in 4G-LTE base stations with more broad adaptation expected in 5G and beyond.

With GaN now rapidly growing in both defense and commercial spaces, it is proper to assess the longevity and long-term potential of the current GaN heterostructure, with the intention of enabling the maximum performance possible. Many of the limitations of conventional GaN amplifiers lie in the foundational layer of the heterostructure—the buffer. While not directly involved in device transport, the buffer material properties have a profound impact on device characteristics and overall performance. In the conventional AlGaN/GaN heterostructure, where the channel is an extension of the GaN buffer, there is a lack of a back barrier to confine the 2DEG in the vertical direction. The consequence is a spreading of channel region into the buffer, with the end result being a significant increase in output conductance, limiting device gain and efficiency in the mm-wave regime. Additionally, buffer leakage currents are common with GaN buffers. AlGaN back barriers were introduced to combat this effect, but at the cost of introducing a higher thermal-resistive alloy layer in the path of the heat flow. Heat dissipation continues to be a significant limitation for GaN technology, and the addition of an alloyed back barrier limits it further.

There is a need for a new platform for the future of GaN and other Group IIIN amplifiers that overcomes the above difficulties.

### BRIEF SUMMARY

Herein below, a new platform for the future of GaN amplifiers: aluminum nitride (AlN) is disclosed. The incorporation of aluminum nitride in the form of a buffer layer enables next generation performance in three critical ways. (1) Enhance thermal management; (2) Provide a maximized back barrier, drastically reducing short-channel effects (SCEs) and buffer leakage; (3) Enable an unprecedented level of integration in nitride electronics.

In one instance, the semiconductor component of these teachings includes an undoped AlN buffer layer deposited on a substrate; and at least two structures from following structures: (a) a second epi-layer of a second Group III nitride material epitaxially grown on the undoped AlN buffer layer, wherein a difference between a normal component of a polarization of the second layer of the second Group III nitride material and the not intentionally AlN buffer layer is negative; and wherein there is an energy band offset between valence bands of the undoped AlN buffer layer and the second Group III nitride material; an energy bandgap of the second Group III nitride material being smaller than an energy bandgap of AlN; and a 2D hole gas at a heterojunction between the undoped AlN buffer layer and the second layer of the second Group III nitride material; or (b) a second epi-layer of a second Group III nitride material epitaxially grown on the undoped AlN buffer layer; wherein a difference between a normal component of a polarization of the second layer of the second Group III nitride material and the not intentionally doped AlN buffer layer is negative; and wherein there is an energy band offset between valence bands of the undoped AlN buffer layer and the second Group III nitride material; an energy bandgap of the second Group III nitride material being smaller than an energy bandgap of AlN, a 2D hole gas at a heterojunction between the not intentionally doped AlN buffer layer and the second layer of the second Group III nitride material; and a third Group III-N barrier layer deposited over a portion of the second epi-layer of the second Group III nitride material; a thickness a of the third Group III-N barrier layer and a composition of a third Group III-N material selected such that a two dimensional electron gas (2DEG) forms at a heterojunction between the second epi-layer of the second Group III nitride material and the third Group III-N barrier layer; or (c) a first electrically conductive layer under another portion of the not intentionally doped AlN buffer layer; the first electrically conductive layer being one of embedded deposited in a volume removed from the substrate or deposited on a surface of the not intentionally doped AlN buffer layer where the surface would have been previously adjacent to the substrate; and a second electrically conductive layer disposed on another surface of the another portion of the undoped AlN buffer layer; the second electrically conductive layer being opposite the first electrically conductive layer. Instantiations of structures (a), (b) and (c) are shown in FIGS. 1A, 1B, 1C.

For a better understanding of the present teachings, together with other and further objects thereof, reference is made to the accompanying drawings and detailed description and its scope will be pointed out in the appended claims.

### BRIEF DESCRIPTION OF THE DRAWINGS

FIG. 1A shows. a cross-section of an instantiation of the aluminum nitride (AlN) platform of these teachings;

FIG. 1B shows. a cross-section of another instantiation of the aluminum nitride (AlN) platform of these teachings;

FIG. 1C shows a cross-section of yet another instantiation of the aluminum nitride (AlN) platform of these teachings;

FIGS. 2A, 2B, 2C show (A) Thermal conductivities of some commonly used materials in III-nitride electronics, (B) an instance of a schematic of the measurement system, (C) Theoretical thermal boundary resistances (TBR) calculated using Density mismatch model (DMM) under Debye approximation;

FIGS. 3A, 3B, 3C show (B) a cross-sectional representation of an instantiation of a fully processed, T-gated AlN/GaN/AlN HEMT, (A) a transmission electron microscope (TEM) image of the MBE-grown AlN/GaN/AlN heterostructure demonstrating atomically-sharp interfaces, (C) the energy band diagram for the heterostructure, showing the predicted formation of both a 2DEG and 2DHG;

FIG. 3B2 is an annotated expanded version of FIG. 3B;

FIG. 4 highlights the top barrier thickness of AlN, InAlN, and AlGaN used to generate a high density (2×10¹³) 2DEG; AlN uses a thickness of 1.4 nm, while InAlN uses 6 nm; In the case of the AlGaN barrier, a 2DEG density of 1.4×10¹³ is achieved at a barrier thickness of 20 nm;

FIGS. 5A, 5B, 5C show (a) Hard breakdown for three HEMTs with varied gate-drain separations; (b) Breakdown voltage scaling as a function of gate-drain separation ranging from 0.27 to 5.1 μm; (c) Johnson figure of merit benchmark plot comparing the AlN/GaN/AlN HEMT to state-of-the-art GaN HEMTs with submicron LGD and no field plate;

FIG. 6A, 6B show (a) the output characteristics for an AlN/GaN/AlN HEMT, demonstrating Ron=0.8 Ω·mm and high on-current of 3.3 A/mm; (b) Initial load-pull characteristics for these devices, showing 55% power added efficiency (PAE), but with significant gain compression that limits output power to 2.8 W/mm at 6 GHz;

FIG. 7 shows the 2D hole gas in GaN/AlN heterostructures compared to other reported 2DHGs on in III-nitrides;

FIGS. 8A-8E show (a) Cross-section representation and (b) SEM image of a fully processed GaN/AlN pFET, with energy band diagrams highlighting the (c) contact and (d) gated regions; Note the channel region is completely undoped; (e) A benchmark plot of III-nitride pFETs, with the highest on-currents achieved by the GaN/AlN heterostructure;

FIG. 8A2 is an annotated expanded version of FIG. 8A;

FIGS. 9A, 9B, 9C show (a) the output characteristics for a GaN/AlN pFET with −100 mA/mm on-current; (b) The log and (c) linear transfer curves for the same device, highlighted by a transconductance of 15 mS/mm;

FIG. 10 show another instantiation of the Group III nitride p-FET semiconductor device;

FIG. 11 shows one instantiation of a substrate-integrated waveguide (SIW); and

FIG. 12 shows a top view of one instantiation of a filter using SIWs.

### DETAILED DESCRIPTION

A new platform for the future of GaN amplifiers: aluminum nitride (AlN) is disclosed hereinbelow.

“Not intentionally doped AlN,” as used herein, refers to AlN deposited without intentionally introduced doping. Not intentionally doped AlN can have, in some instances, concentrations of Oxygen of about 4×10¹⁸ cm⁻³ and, in some instances, concentrations of Silicon slightly higher than 7×10¹⁷ cm⁻³ (see, for example, N. T. Son, M. Bickermann, and E. Janzén, Shallow donor and DX states of Si in AlN, APPLIED PHYSICS LETTERS 98, 092104 (2011), which is incorporated by reference herein in its entirety and for all purposes).

“Group III,” as used here in, refers to a group of elements in the periodic table including what are now called Group 13 elements: boron (B), aluminum (Al), gallium (Ga), indium (In), thallium (Tl).

“Metalized vias,” as used herein, which are also referred to as Through Substrate Vias (TSV), are holes, extending vertically from one layer to another layer, an inner surface of the hole having an electrically insulating layer (in order to electrically isolated from intervening layers) and having an electrically conducting material deposited at least the electrically insulating layer on the inner surface (more usually filing the inner region0. (See Susan L. Burkett et al., Tutorial on forming through-silicon vias, Journal of Vacuum Science & Technology A 38, 031202 (2020) and Section 1,3.1 in Marco Rovitto, Electromigration Reliability Issue in Interconnects for Three-Dimensional Integration Technologies, Pd. D thesis, Technischen Universitat Wien, Austria, December 2016, all of which are incorporated by reference herein in their entirety and for all purposes.)

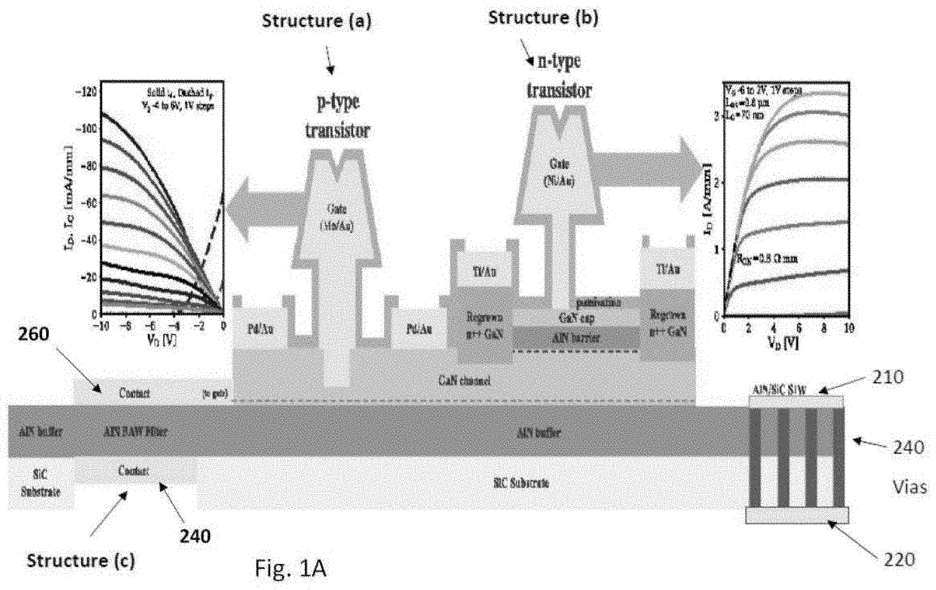

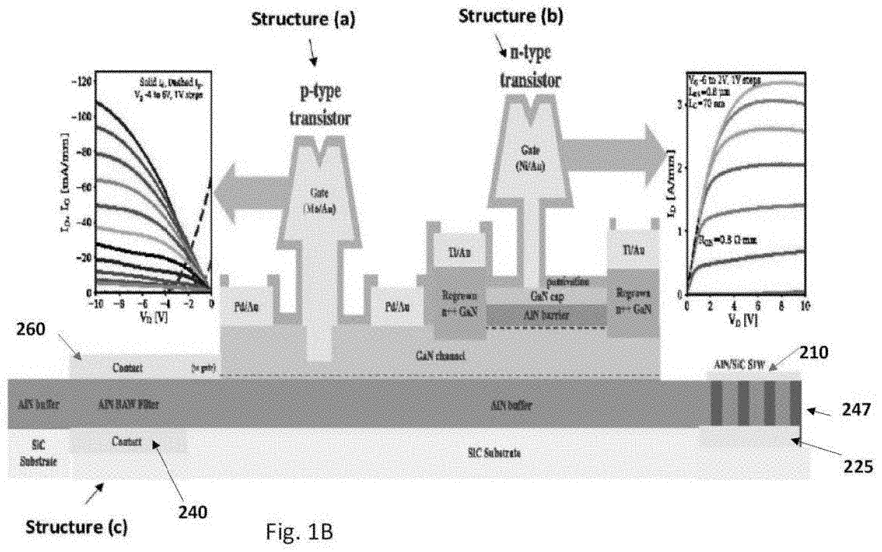

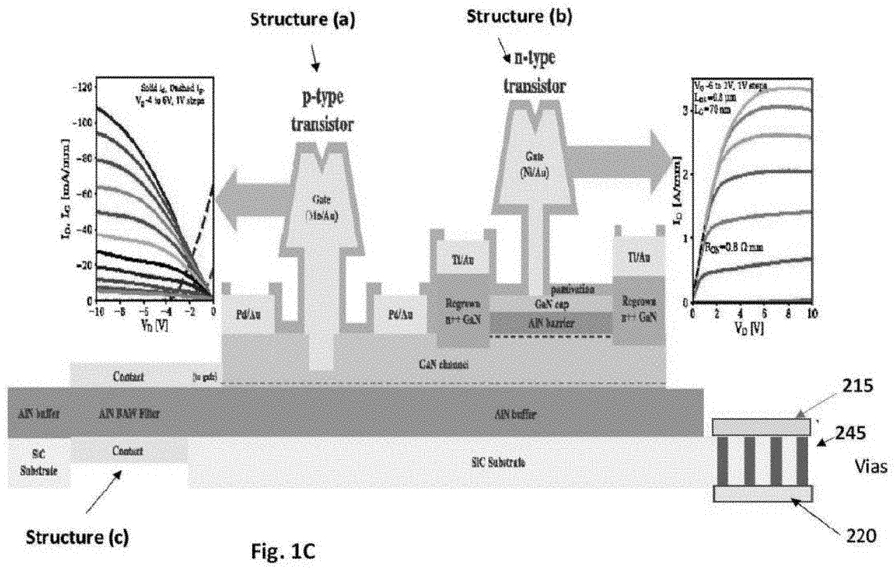

In one instance, the semiconductor component of these teachings includes an undoped AlN buffer layer deposited on a substrate; and at least two structures from following structures: (a) a second epi-layer of a second Group III nitride material epitaxially grown on the undoped AlN buffer layer, wherein a difference between a normal component of a polarization of the second layer of the second Group III nitride material and the not intentionally AlN buffer layer is negative; and wherein there is an energy band offset between valence bands of the undoped AlN buffer layer and the second Group III nitride material; an energy bandgap of the second Group III nitride material being smaller than an energy bandgap of AlN; and a 2D hole gas at a heterojunction between the undoped AlN buffer layer and the second layer of the second Group III nitride material; or (b) a second epi-layer of a second Group III nitride material epitaxially grown on the undoped AlN buffer layer; wherein a difference between a normal component of a polarization of the second layer of the second Group III nitride material and the not intentionally doped AlN buffer layer is negative; and wherein there is an energy band offset between valence bands of the undoped AlN buffer layer and the second Group III nitride material; an energy bandgap of the second Group III nitride material being smaller than an energy bandgap of AlN, a 2D hole gas at a heterojunction between the not intentionally doped AlN buffer layer and the second layer of the second Group III nitride material; and a third Group III-N barrier layer deposited over a portion of the second epi-layer of the second Group III nitride material; a thickness a of the third Group III-N barrier layer and a composition of a third Group III-N material selected such that a two dimensional electron gas (2DEG) forms at a heterojunction between the second epi-layer of the second Group III nitride material and the third Group III-N barrier layer; or (c) a first electrically conductive layer under another portion of the not intentionally doped AlN buffer layer; the first electrically conductive layer being one of embedded deposited in a volume removed from the substrate or deposited on a surface of the not intentionally doped AlN buffer layer where the surface would have been previously adjacent to the substrate; and a second electrically conductive layer disposed on another surface of the another portion of the undoped AlN buffer layer; the second electrically conductive layer being opposite the first electrically conductive layer. Instantiations of structures (a), (b) and (c) are shown in FIGS. 1A, 1B, 1C.

In one instance, structure (a) also includes a first slab of p-doped third Group III nitride material disposed on the second epi-layer of the second Group III nitride material, a second slab of p-doped third Group III nitride material disposed on the second epi-layer of the second Group III nitride material; the second slab of p-doped third Group III nitride material being spaced apart from the first slab of p-doped third Group III nitride material, and a first electrically conductive contact disposed over a surface of the second epi-layer of the second Group III nitride material, the surface being located between the first slab of p-doped third Group III nitride material and the second slab of p-doped third Group III nitride material and opposite a surface of the first layer of the not intentionally doped AlN buffer layer on which the second epi-layer of the second Group III nitride material is grown.

In another instance, structure (a) further includes a second electrically conductive contact disposed over a portion of the first slab of p-doped third Group III nitride material, and a third electrically conductive contact disposed over a portion of the second slab of p-doped third Group III nitride material. The first electrically conductive contact is disposed away from the third and second electrically conductive contacts.

In one instantiation, wherein the second Group III nitride material is GaN. In that instantiation, one integration element enabled by an AlN platform is the addition of the GaN/AlN p-channel FET, allowing for true, high-current nitride CMOS-like complementary circuits for the first time in wide bandgap semiconductors.

In one instance, structure (b) also includes an n-doped fourth Group III nitride material drain region recessed into at least the second epi-layer of the second Group III nitride material, the-doped fourth Group III nitride material drain region extending from a first end of the structure (b) to less than half a distance from the first end of the structure (b) to a second end of the structure (b), an n-doped fourth Group III nitride material source region recessed into at least the second epi-layer of the second Group III nitride material, the n-doped fourth Group III nitride material drain region extending from the second end of the structure (b) to less than half a distance from the first end of the structure (b) to a second end of the structure (b), the second epi-layer of the second Group III nitride material between the n-doped fourth Group III nitride material drain region and the n-doped fourth Group III nitride material source region forming a channel layer, and a gate electrode disposed above the third Group III-N barrier layer and between and not in contact with the n-doped fourth Group III nitride material source region and n-doped fourth Group III nitride material drain region.

In another instance, structure (b) further includes a fifth Group III-N material passivation layer grown on the third Group III-N barrier layer. In yet another instance, in structure (b), the gate electrode includes a neck portion, the neck portion having a first width, and second portion, disposed on the first portion, and having an average width larger than the first width.

In one instantiation, the second Group III nitride material is GaN, a third Group III-N material is AlN, and the fourth Group III nitride material is GaN. In that instantiation, the AlN/GaN/AlN heterostructure produces high density, 2D electron and hole gases simultaneously.

In addition to enabling nitride CMOS and RF amplifiers on the same platform, AlN also allows for the full integration of passive components. AlN BAW filters, using epitaxial deposited layers (which is structure (c) in FIGS. 1A, 1B and 1C), can seamlessly integrate via the AlN buffer region. Along with signal isolation (BAW filter), computation (CMOS), and amplification (AlN/GaN/AlN HEMT), the AlN platform will allows for the integration state-of-the-art SiC substrate integrated waveguides (SIWs). The AlN platform of these teachings (instantiations of which are illustrated in FIGS. 1A, 1B, and 1C, with AlN HEMT performance potential and unprecedented integration capability, will bolster GaN amplifiers as the forefront technology for the future of mm-wave amplification, and will open the door for an array of new applications previously unachievable with nitride electronics. The incorporation of an aluminum nitride buffer improves upon existing n-type GaN amplifiers and allow for the inclusion of high-current p-type transistors on the same heterostructure. Aluminum nitride also enables integration of both bulk acoustic wave (BAW) filters and substrate-integrated waveguides (SIW), providing a fully-integrated monolithic RF signal-processing solution. (The pFET output characteristics in FIGS. 1A, 1B and 1C are Bader S J, Chaudhuri R, Hickman A, Nomoto K, Bharadwaj S, Then H W, Xing H G and Jena D 2019 Technical Digest—International Electron Devices Meeting, IEDM 2019-December 4-7; U.S. Patent Application Publication No. 2020/0144407, by Bader et al., published May 7, 2020, all of which are incorporated by reference herein in their entirety and for all purposes.)

Thermal Advantage of Aluminum Nitride

High-frequency performance of GaN HEMTs stems directly from the material properties such as band-gap and electron transport. A wide bandgap results in a higher breakdown voltage, and a high electron mobility and saturation velocity of the carrier results in higher intrinsic frequency of operation. These properties predict an intrinsic limit on the output power a material platform can support. However, a large discrepancy is observed when the experimentally measured output power densities are compared to the intrinsic material output power limit for GaN RF HEMTs, especially at lower cutoff frequencies (f_{T}). This difference is explained by considering the effect of heat dissipation during the amplifier operation. In a simple picture, a power amplifier (PA) transforms a low-power input AC signal into an amplified higher-power AC output signal, with the difference coming from the applied DC bias power. In a real world device, only a part of this DC power goes into amplifying the output (depending on the amplifier efficiency)—the remaining power is transferred into the surroundings and the semiconductor material itself in the form of heat. This leads to a highly localized rise in temperature on the drain side of the transistor channel, which deteriorates the electronic properties such as mobility, saturation velocity, limiting the maximum output power that can be extracted from the transistor. The heating is also responsible a thermal stress gradient in the device semiconductor layers which reduces the reliability and lifetime of the transistor.

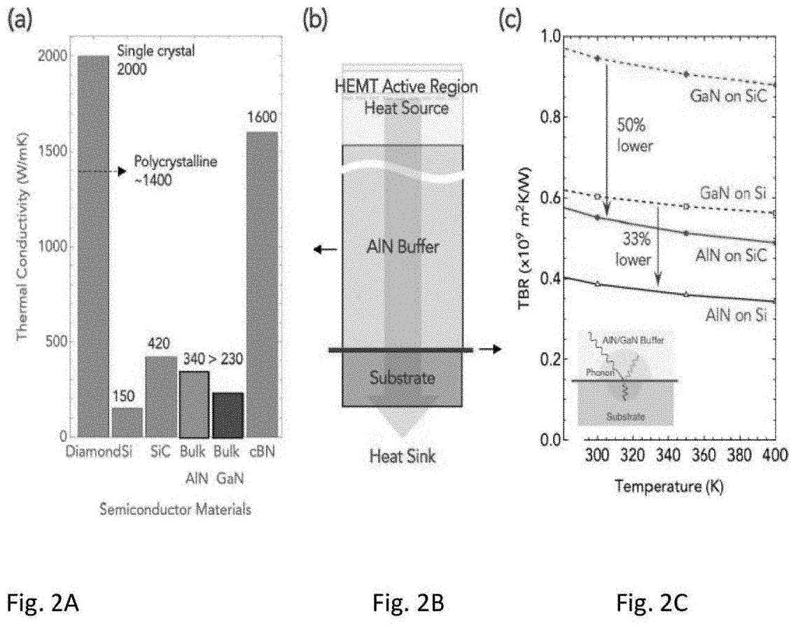

Therefore, it is important for any high power RF platform to efficiently conduct the heat away from the active region channel in order to push the performance. In an RF HEMT, the drain side of the gate, where the electric field peaks, acts as a heat source. In the absence of a top heat-conducting layer, the heat primarily conducts through the buffer, into the substrate and to the heat sink at the bottom—as illustrated in FIG. 2B. The thermal resistances between the channel and sink therefore play an important role in determining the channel temperature and thereby the device performance. The thermal resistances in this setup are in two forms (1) (inverse of) thermal conductivity of the buffer and substrate materials, and (2) thermal boundary resistances between two materials. Both these resistances are manifestations of the physics of heat transport via phonons and therefore are intrinsic to the semiconductor materials if one considers an ideal crystal material. This allows us to compare the AlN platform (AlN buffer on substrate), with the conventional GaN platform (GaN buffer on substrate) and highlight the advantage which the AlN provides us with respect to the expected thermal performance.

FIG. 2A shows in (2A) thermal conductivities of some commonly used materials in III-nitride electronics. Ternary and quaternary alloys are expected to have lower conductivities than their constituent binary counterparts. FIG. 2B shows an instance of a schematic of the measurement system, FIG. 2C shows theoretical thermal boundary resistances (TBR) calculated using Density mismatch model (DMM) under Debye approximation. AlN is expected to have a lower TBR compared to GaN buffers on common substrates such as Silicon and Silicon carbide. A perfect homoepitaxially grown AlN on single crystal AlN substrates will not have any thermal boundary resistance as a boundary is not defined in that case.

FIG. 2A compares the experimentally measured thermal conductivity values of commonly encountered semiconductor materials in III-nitride devices. Silicon (111) and Silicon carbide (SiC) are commonly used substrates for these family of devices. SiC, with a high thermal conductivity of ˜420 W/mK is the substrate of choice for effective thermal management in the current state-of-art RF GaN HEMTs. Single-crystal diamond and cubic-boron nitride (c-BN) have the highest thermal conductivities. In III-nitrides, AlN has a higher thermal conductivity of 340 W/mK compared to 230 W/mK of single-crystal GaN. It is clear from these values that an AlN buffer holds an advantage over a GaN buffer in terms of heat conduction away from the active region.

An additional factor to consider is the thermal boundary resistance (TBR) between the substrate and the buffer layer. TBR is an intrinsic property of an interface where it acts as a resistance to heat flow and leads to a rise in temperature. In a microscopic picture, according to the diffusive mismatch model (DMM), the TBR at an interface between two ideal materials arises due to the difference in density of available states for a heat carrying phonon to scatter into when moving from one material to the other. The calculated TBR between AlN and GaN buffer layers and commonly used Si(111) and SiC substrates are shown in FIG. 2C. The Debye density of states approximation has been used. This model predicts that an AlN buffer should have a lower TBR compared to GaN buffer on both SiC and Si substrates, by ˜50% and ˜33% respectively. Experimental measurement of TBRs for these structures have yielded values a couple of orders higher which is attributed to the non-ideal crystal structure near the nucleation interface. This is especially true in case of GaN, where AlN nucleation layers and/or stress-management layers with lower crystal quality result in high TBRs. AlN, with a lower lattice mismatch, can be directly grown on SiC with a better crystal quality and thus lower a TBR. Recent availability of high quality single-crystal substrates has opened up the possibility of homoepitaxial growth of GaN and AlN on bulk GaN and bulk-AlN substrates respectively, in which TBR should be non-existent. Even in this case, comparing to GaN on GaN, AlN on bulk AlN holds the theoretical thermal advantage due to higher thermal conductivity.

AlN buffer leads to a better thermal management in RF HEMT when compared to a GaN buffer grown heteroepitaxially on Si, SiC or homoepitaxially on bulk substrates. This leads to a performance boost in the AlN buffer devices, especially for high power RF transistors. However, it should be noted that the actual epitaxial crystal quality determines the value of thermal resistances encountered in a real device. Hence the translation of these expected device performance boosts depends heavily on the quality of the material grown and growth optimizations.

Growth of Aluminum Nitride Devices

The first step in the design of any high-performance electronic device is the crystal growth. An optimized crystal growth provides a starting material for developing the device fabrication process. Research into growth of III-nitrides have a rich history of over 5 decades. The epitaxial techniques used for growth are metal-organic chemical vapour deposition (MOCVD) and molecular beam epitaxy (MBE). Traditionally in GaN device growths, AlN has been used either as nucleation layers to counter the lattice mismatch between GaN and the substrate and improve quality of subsequent layers, or as thin barrier/spacer layers in Al(Ga)N/GaN HEMT structures.

Recent research in electronics-grade AlN growth has been driven by UV LEDs and lasers (on sapphire substrates or bulk single-crystal substrates), and by transistors on AlN. These require AlN layers much thicker than those used in GaN HEMTs, typically 0.5-1 μm.

Taking a closer look at Al-polar AlN growth for transistor applications, the thick AlN buffer is the building-block of the AlN platform. Various groups have demonstrated the growth of AlN buffer layer for HEMTs using MOCVD plasma-assisted (PA) MBE, ammonia (NH3) MBE. The AlN layers have been grown on various substrates such as MOCVD-grown AlN on Sapphire templates, 6H—SiC and Bulk single crystal AlN as starting substrates. 6H-SiC is typically the substrate of choice for high-power RF transistors due to its low lattice mismatch with respect to AlN, high thermal conductivity and availability of large wafers. Furthermore, it opens up the prospect of integration with substrate integrated waveguide technologies (SIW) using through substrate vias (TSVs). Typical dislocation densities in devices on MBE-grown 1 um thick AlN buffers on 6H-SiC range in ˜10⁹ cm⁻². It should be noted that fully-strained AlN on SiC films up to 700 nm have been demonstrated with threading dislocation densities in the mid 10⁸ cm². Reducing the dislocation densities should reduce the gate leakage in Schottky gated transistors, thereby translating in high on-off ratios. Towards this, recent efforts gone into successfully demonstrating high-quality homoepitaxial on single crystal AlN substrates by optimized crystal surface cleaning.

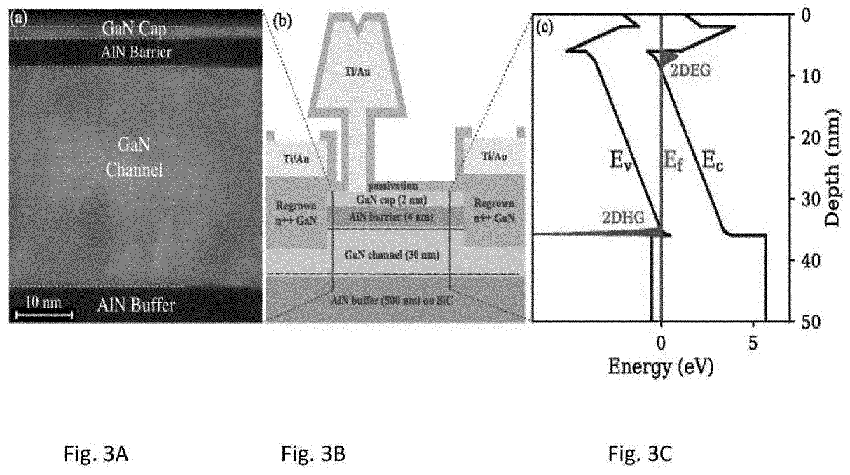

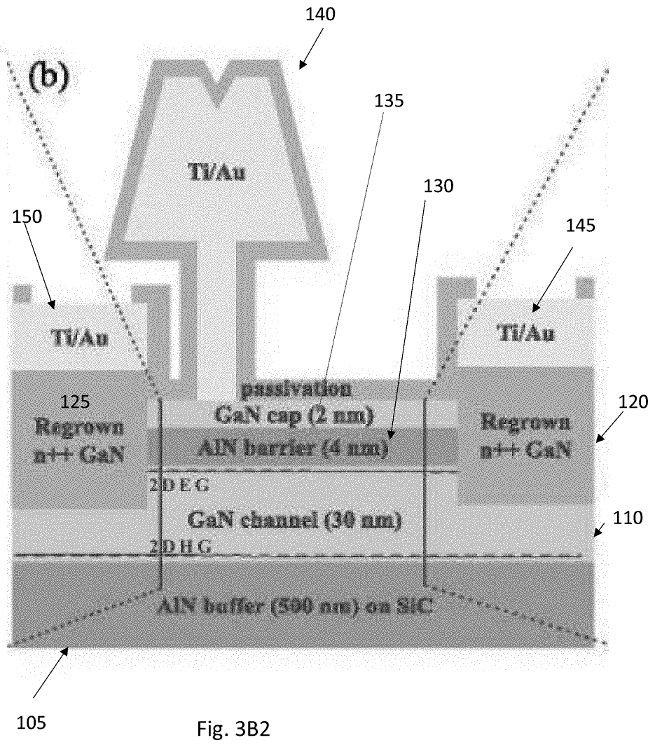

Because of its wide bandgap and high activation energies of impurity dopants, these AlN layers show low buffer leakage, ideal for a transistor. On top of this buffer, an active region with a 2D electron gas (2DEG) is grown for n-channel devices, as shown in FIGS. 3A-3C. A GaN layer, typically 20-200 nm thick, is used as the channel layer. GaN layers up to 30 nm thick have been shown to be psuedomorphically strained to the AlN buffer. An AlN barrier then grown on top generates a high-density 2DEG at the AlN/GaN interface of densities-˜2-4×10′¹³ cm⁻². The channel thickness and the barrier thickness are the knobs to fine tune the 2DEG density. Typical room temperature Hall mobilities in these 2DEGs have been measured to be around ˜700 cm²/V·s at high densities of ˜2-3×10¹³ cm⁻². Even though this number is lower than mobilites (˜1800 cm²/V·s reported for lower density 2DEG (mid 10¹² cm⁻²) in GaN HEMTs, the high charge densities and high conductivities enabled low R_{ON} and high on-current densities in AlN/GaN/AlN HEMTs. A few groups have also demonstrated a higher mobility 2DEG 1400-2000 cm²/V·sat a 2DEG density of ˜1×10¹³ cm² by using an AlGaN barrier instead of AlN barrier. However, this gives up the advantage of having a relaxed barrier which is preferred for the reliability of an RF HEMT.

The AlN buffer also offers a platform for p-channel devices due to the ability to generate a high density 2DHG at the GaN channel/AlN buffer interface (see Chaudhuri R, Bader S J, Chen Z, Muller D A, Xing H G and Jena D 2019 Science 365 1454-1457 ISSN 10959203 and Chaudhuri et al., U.S. Patent Application Publication No. 2021/0249513, published Aug. 12, 2021, both of which are incorporated by reference herein in their entirety and for all purposes). This is the p-type analog of the Al(Ga)N/GaN HEMT structure. It does not need any acceptor doping to generate holes, with an undoped GaN/AlN exhibiting a hole density of ˜5×10¹³ cm⁻² and Hall mobility ˜25 at room temperature.

The presence of both a high-density 2DEG and 2DHG on the same platform makes it exciting for wide-bandgap devices, with record p-channel and n-channel devices demonstrated.

AlN/GaN/AlN Power Amplifier

FIGS. 3A, 3B, 3C show (B) a cross-sectional representation of an instantiation of a fully processed, T-gated AlN/GaN/AlN HEMT, (A) a transmission electron microscope (TEM) image of the MBE-grown AlN/GaN/AlN heterostructure demonstrating atomically-sharp interfaces, (C) the energy band diagram for the heterostructure, showing the predicted formation of both a 2DEG and 2DHG. FIG. 3B2 is an annotated expanded version of FIG. 3B.

Referring to FIG. 3B2, in the instantiation shown therein, an AlN/GaN/AlN power amplifier is shown including an AlN buffer layer 105 formed on a substrate, such as SiC, Aluminum oxide, Silicon, AlN, or the like. The AlN buffer layer 105 is formed to a thickness in a range between about 350 nm to about 500 nm, although other thicknesses are within the scope of these teachings. A GaN channel layer 110 is epitaxially grown on the AlN buffer layer 105 so that the lattice of the GaN channel layer 110 is matched to the lattice of the AlN buffer layer 105. The GaN layer 110 is selected such that a 2D Hole gas format the AlN/GaN heterostructure. Although a GaN thickness of 30 nm is shown, other thicknesses are within the scope of these teachings. Other materials, besides GaN, are also within the scope of these teachings. An AlN barrier layer 130 is formed on the GaN channel layer 110. A 2D electron gas forms at the GaN channel layer/AlN barrier layer heterostructure. A GaN cap layer 135 formed on the AlN barrier layer 130. Although to a thickness of about 2 nm is shown for the cap layer 135, other thicknesses may be used. Source and drain recesses are formed spaced apart in the power amplifier materials stack and provide for the formation of the formation of n++ GaN source and drain regions 120 and 125, respectively. Ohmic contacts 145, 150 are formed on the n++ GaN source and drain regions 130 and 135. In some instantiations, the ohmic contacts include a metal or a combination of metals, such as Ti and/or Au. Other metals may also be used. A gate electrode 140 including a neck portion, the neck portion having a first width, and second portion, disposed on the first portion, and having an average width larger than the first width is formed, the neck portion being disposed on the GaN cap layer 135. A passivation layer is be formed over the ohmic contacts 145, 150, the T-shaped gate electrode 140 and the GaN cap layer 135.

Thoughtful III-Nitride heterostructure design is the foundation upon which all high-power, mm-wave devices should be built. As previously mentioned, aluminum nitride is the premier III-nitride buffer material, as it simultaneously confines the 2DEG, electrically insulates, and thermally conducts better than GaN. Equally as important for mm-wave performance is the material choice for the top barrier. For RF amplifiers, high transconductance and gain are critical, and it is therefore necessary to scale the barrier as thin as possible. This is where material choice is important, as the top barrier material can limit vertical scaling by requiring a certain thickness to generate sufficient charge density. To quantify this, a self-consistent 1D Schrodinger-Poisson solver was used to simulate the barrier thickness required to generate a 2DEG high density of 2×10¹³ cm⁻² for AlGaN, InAlN, and AlN top barriers on Ga-polar GaN channels. The Al0.3Ga0.7N barrier, even at 20 nm thick, is unable to achieve the desired high density 2DEG, instead showing 1.4×10¹³ cm⁻². Also popular in contemporary GaN HEMT design is the InAlN barrier. In_{0.17}Al_{0.83}N fares better, generating a 2×10¹³ cm⁻²2DEG at a barrier thickness of 6 nm. Notably, an AlN top barrier of just 1.4 nm able to meet the 2×10¹³ cm⁻²2DEG threshold. This reduction is due to the increased polarization difference at the AlN/GaN interface. The reduced top barrier thickness provided by AlN is important for future ultra-scaled mm-wave devices, as it has been empirically shown that transconductance rapidly falls off when the gate length to barrier thickness ratio (L:tb) is less than five. This is due to short channel effects (SCEs) that can be attributed to the gate's lack of control, as a result of the increased distance between the gate and the 2DEG. It is important to note that SCEs are also heavily dependent on the presence of a back barrier, and that both a back barrier and thin top barrier are necessary to effectively mitigate SCEs for ultra-scaled HEMTs. While L:tb<5 may shift depending on the full heterostructure design, it can serve as a rule-of-thumb for the gate length limit for commercially-viable device design. Going off this rule, to achieve RF devices with a high density 2DEG and without significant SCEs, an AlGaN barrier will require an L of 100 nm, and InAlN requires L=30 nm. This is a factor to be noted, as gate lengths as short as 20 nm have already been demonstrated.

With an ideal AlN top barrier of 1.4 nm, and accounting for the fact that the centroid of the 2DEG is ˜1 nm from the interface, SCEs can be prevented to a gate length of 10 nm. To maximize vertical scaling capabilities, and to take advantage of state-of-the-art gate technology, an aluminum nitride top barrier is advantageous.

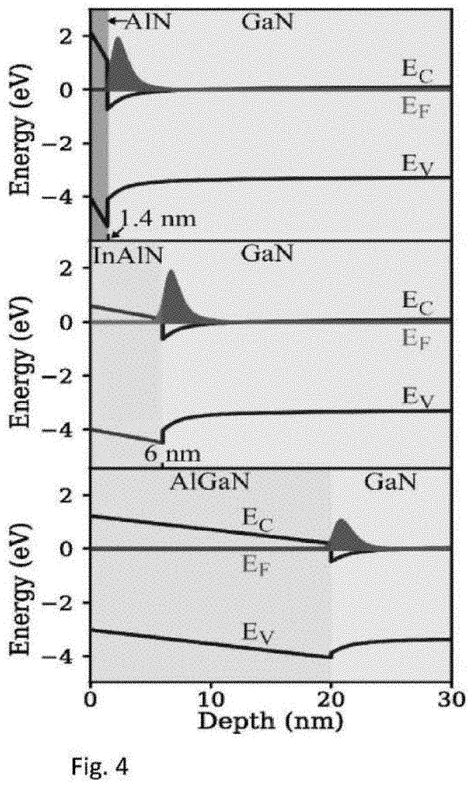

FIG. 4 highlights the top barrier thickness of AlN, InAlN, and AlGaN required to generate a high density (2×10¹³) 2DEG. AlN requires a thickness of 1.4 nm, while InAlN requires 6 nm. In the case of the AlGaN barrier, a 2DEG density of 1.4×10¹³ is achieved at a barrier thickness of 20 nm;

The incorporation of AlN in both the top barrier and buffer results in an AlN/GaN/AlN heterostructure. Devices on this heterostructure, grown by molecular beam epitaxy (MBE), were first demonstrated in 2012. In these teachings, the GaN channel is scaled to 30 nm in thickness. This improves confinement of the 2DEG and minimizes the distance from the active region to the more thermally conductive AlN buffer. Another effect of having a thin GaN channel is that it can be psuedomorphically strained to the AlN buffer. This translates up through the GaN channel to the AlN top barrier, resulting in a relaxed top barrier that increases device reliability and is capable of preventing significant leakage currents at a thickness of just 1 nm due to the high conduction band offset between GaN and AlN.

For high-power, mm-wave applications, AlN boasts the largest bandgap, and therefore the largest critical electric field, of the III-nitrides. This is advantageous for increasing device breakdown, which can dramatically increase the maximum output power. Accordingly, the breakdown characteristics of AlN/GaN/AlN HEMTs were investigated for gate-drain lengths_{(LGD)} ranging from 0.27 to 5.1 μm (Hickman A, Chaudhuri R, Bader S J, Nomoto K, Lee K, Xing H G, Member S, Jena D, Member S and In A 2019 IEEE Electron Device Letters 40 1293-1296, incorporated by reference herein in its entirety and for all purposes). The breakdown voltage metric is defined as the voltage at which ID≥1 mA/mm. The devices were covered in Fluorinert during the measurement process.

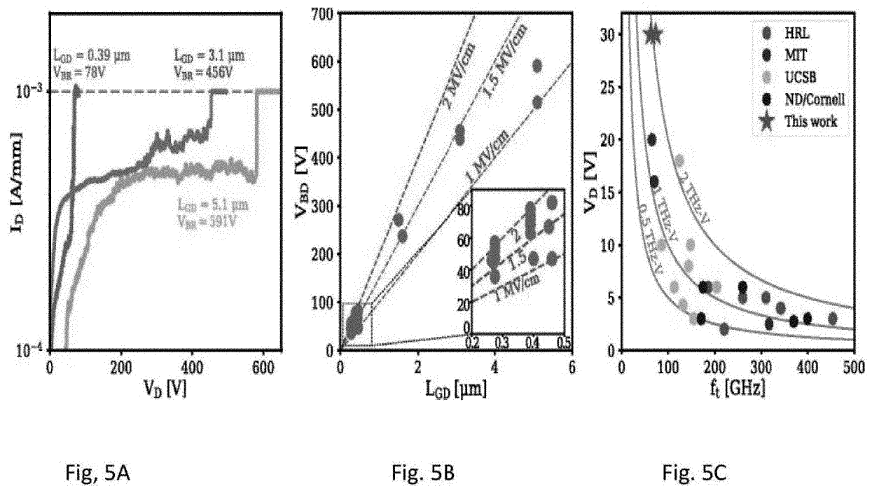

FIG. 5A shows the three terminal off-state breakdown of three AlN/GaN/AlN HEMTs with varied gate-drain distances. (See Hickman A, Chaudhuri R, Bader S J, Nomoto K, Lee K, Xing H G, Member S, Jena D, Member S and In A 2019 IEEE Electron Device Letters 40 1293-1296, and Hickman et al., U.S. Patent Application Publication No. US 2020/0388701 A1, published on Dec. 10, 2020, both of which are incorporated by reference herein in their entirety and for all purposes.) Among all devices, the highest breakdown voltage observed is VBD=591 V (LGD=5.1 μm), corresponding to an average electric field (EBD) of 1.16 MV/cm. All measured devices had average electric fields above 1 MV/cm at breakdown, with 80% of RF devices showing average breakdown fields above 1.5 MV/cm and up to 2 MV/cm. Prior to breakdown, the gate current is found to be roughly equal to the drain current. As a result, the breakdown is likely due to gate-drain leakage and not avalanche or channel breakdown, and therefore is far from the material limits. While the breakdown mechanics of GaN HEMTs in general are still not fully understood, the consistently high breakdown fields observed in AlN/GaN/AlN HEMTs are promising for the RF amplifier potential of the heterostructure. The high breakdown voltage translates to high operating voltage, as demonstrated by the small-signal performance at a drain bias of 30 V, benchmarked in FIG. 5C, yielding a Johnson figure of merit value of 2.2 THz·V. (FIG. 5B shows Breakdown voltage scaling as a function of gate-drain separation ranging from 0.27 to 5.1 μm.)

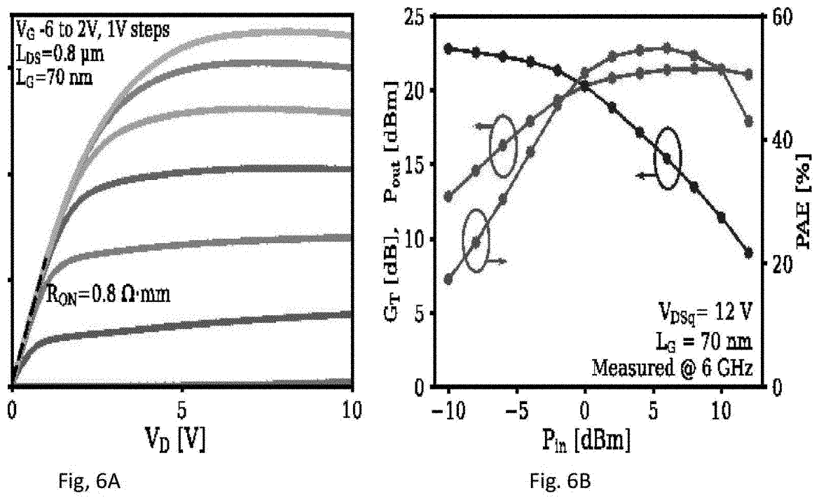

More recently, AlN/GaN/AlN HEMTs were fabricated for large-signal amplification measurements. The fabrication process for the AlN/GaN/AlN HEMTs is highlighted by MBE-regrown contacts and EBL-defined T-gates, thus far achieving contact resistances of 0.13 Ω·mm and gate lengths as short as 50 nm. These T-gated devices showed on-currents up to 3.3 A/mm, as shown in FIG. 6A. This high on-current is achieved with an AlN-top barrier thickness of 4 nm and a corresponding charge density of 3×10¹³ cm⁻². Small-signal measurements were performed across a range of gate and drain bias points, with the best single bias-point ft and fmax=140 and 239 GHz, respectively. (FIG. 6B shows Initial load-pull characteristics for these devices, showing 55% power added efficiency (PAE), but with significant gain compression that limits output power to 2.8 W/mm at 6 GHz.) Finally, initial large-signal measurements were performed for devices on an AlN-buffer, yielding a high power added efficiency (PAE) of 55% and a corresponding output power of 2.8 W/mm at 6 GHz. These devices were severely limited by gain compression, a product of immature fabrication processes, including but not limited to unoptimized SiN-last passivation and isolation achieved by etching rather than ion implantation. The long-term solution to the unoptimized SiN is in-situ passivation. This passivation layer, whether it be SiN, amorphous AlN, or crystalline AlN, will move the surface significantly further away from the channel, mitigating dispersion and subsequent gain compression.

While process immaturity currently limits the output power of RF transistors on the AlN platform, the large breakdown, near-record on-currents, promising small-signal measurements, and high PAE, are indicative of much higher potential. This combined with an optimized heterostructure capable of the most aggressive vertical scaling, suggest that the AlN/GaN/AlN HEMT may be capable of much higher output power (>10 W/mm) at mm-wave frequencies.

AlN-Based CMOS

The prospect of wide-bandgap CMOS, particularly in nitrides, has been limited by the physics and development of the p-type technology. Difficulties for GaN p-type technology are rooted in the heavy valence band effective masses (low mobility) and deep valence energies (hard to contact). Furthermore, the large acceptor ionization energy (150-200 meV for Magnesium results in poor ion activation efficiencies of less than ˜5%. While numerous structures (GaN/AlGaN, GaN/AlInGaN, InGaN/GaN) have used polarization to induce hole gases, it is only on the AlN platform, using a relatively simple Ga-polar GaN/AlN heterostructure, that a 2DHG has been successfully demonstrated in nitrides without the use of doping (see Chaudhuri R, Bader S J, Chen Z, Muller D A, Xing H G and Jena D 2019 Science 365 1454-1457 ISSN 10959203 and Chaudhuri et al., U.S. Patent Application Publication No. 2021/0249513, published Aug. 12, 2021, both of which are incorporated by reference herein in their entirety and for all purposes). This is the p-type analog of the ubiquitous Al(GaN)N/GaN 2DEG which serve as the channel for RF HEMTs.

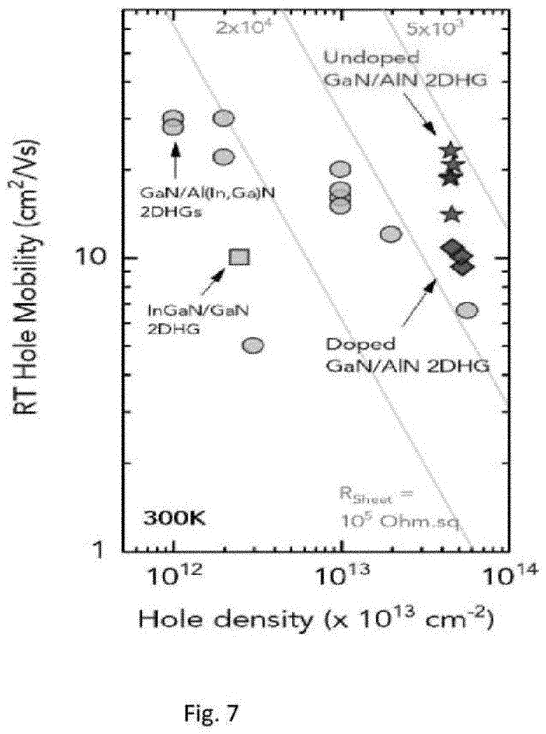

Another issue for GaN p-channels is the low hole mobility compared to electrons, with phonon scattering restricting the room-temperature hole] to ˜50 cm²/Vs (compared to ˜1000-1800 cm²/V·s in GaN 2DEGs). Therefore, in order to minimize sheet resistance, most of the heavy lifting should come from the carrier density. In the same manner as the n-type devices, the GaN/AlN interface provides the maximized polarization difference and has generated 2DHGs densities of ˜5×10¹³ cm², among the highest reported among III-nitrides, as shown in FIG. 7. Note that the only 2DHG reported so far in a heterostructure without acceptor doping is the GaN/AlN 2DHG (see Chaudhuri R, Bader S J, Chen Z, Muller D A, Xing H G and Jena D 2019 Science 365 1454-1457 ISSN 10959203 and Chaudhuri et al., U.S. Patent Application Publication No. 2021/0249513, published Aug. 12, 2021); Comparison to other hole gases on other platforms can be found in Chaudhuri R, Bader S J, Chen Z, Muller D A, Xing H G and Jena D 2019 Science 365 1454-1457 ISSN 10959203 and in Chaudhuri et al., U.S. Patent Application Publication No. 2021/0249513, published Aug. 12, 2021

A more practical, yet just as significant, hurdle to commercial realization of GaN CMOS is the ease of integration of the n-type and p-type devices. In p-type heterostructures that require doping and/or multichannel structures, it is difficult to produce quality, high-density, and easily accessible 2DHGs and 2DEGs on the same heterostructure. Fortunately, the same AlN/GaN/AlN heterostructure used to produce the n-channel FET/HEMT results also contains the exact GaN/AlN interface which has yielded the high 2DHG carrier densities shown in FIG. 7. It has been demonstrated that after a low-power ICP/RIE etch to remove the top AlN barrier layer, the 2DEG is eliminated and only the 2DHG remains, which is reflected in the Hall conductivity changing from n-type to p-type. It is proper to acknowledge that integration challenges remain in this scheme, such as achieving low resistance contacts to an etch-exposed p-channel and recess etch control. Still, it is the combination of simplicity of the heterostructure and quality of the 2DEG and 2DHG that offers a real chance at nitride CMOS, and it is enabled by the AlN platform.

Since the first demonstration, the GaN/AlN p-channel FET (pFET) has shown continuous improvement with device processing iterations. The first GaN/AlN pFET was demonstrated in 2012, with on-currents over −100 mA/mm when the device was pushed to −40 V drain bias and was limited to 3× on/off ratio. In 2018, E-mode pFETs were demonstrated with improved modulation and saturated drain currents of −10 mA/mm at more reasonable biases (VD=−10 V).

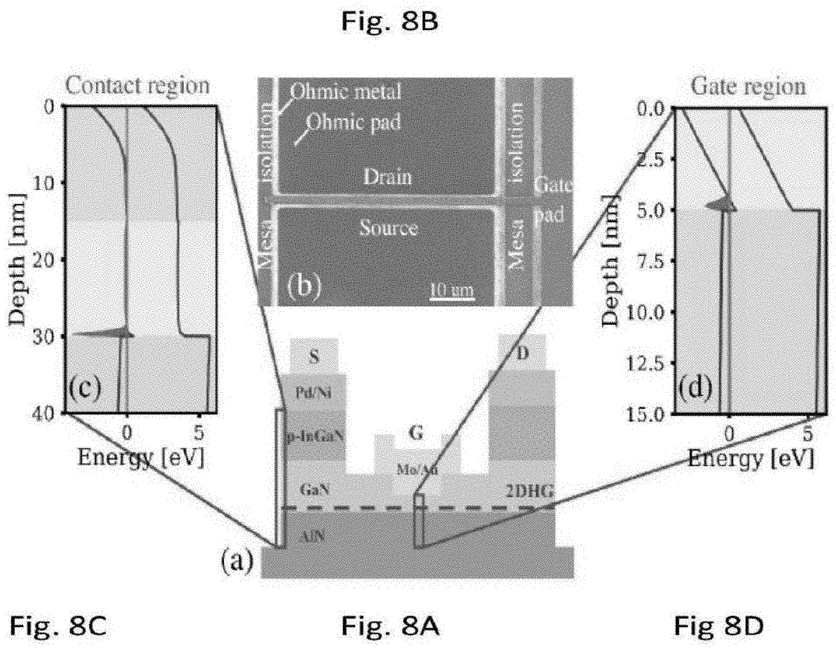

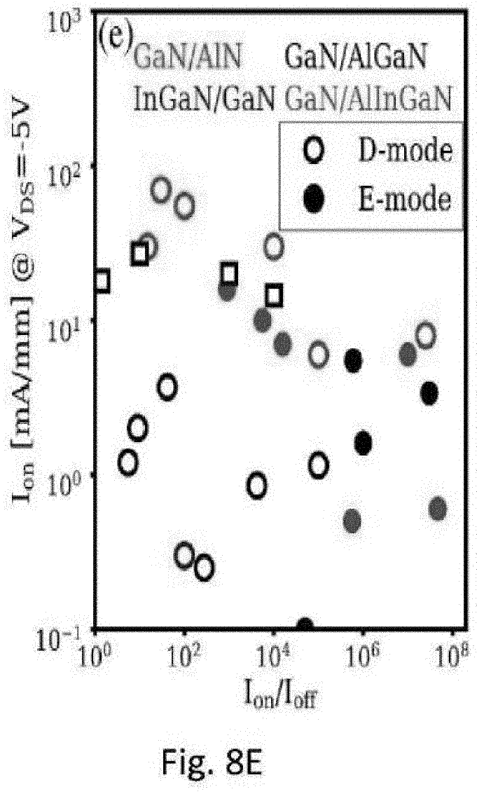

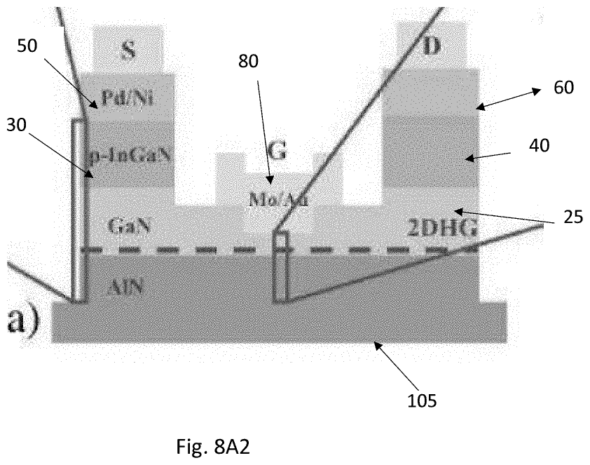

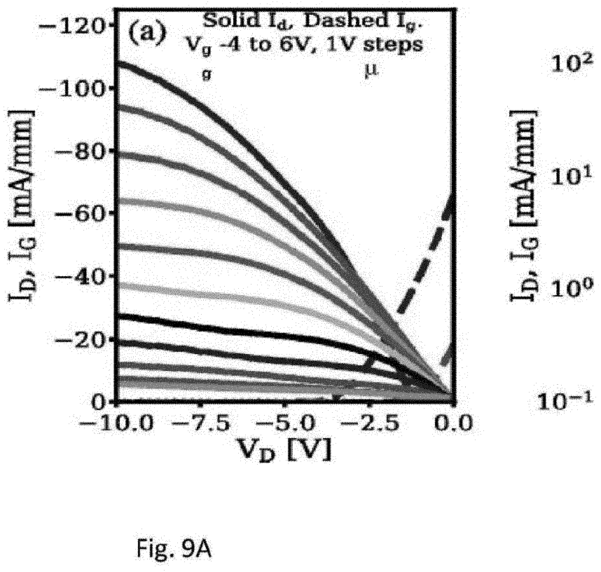

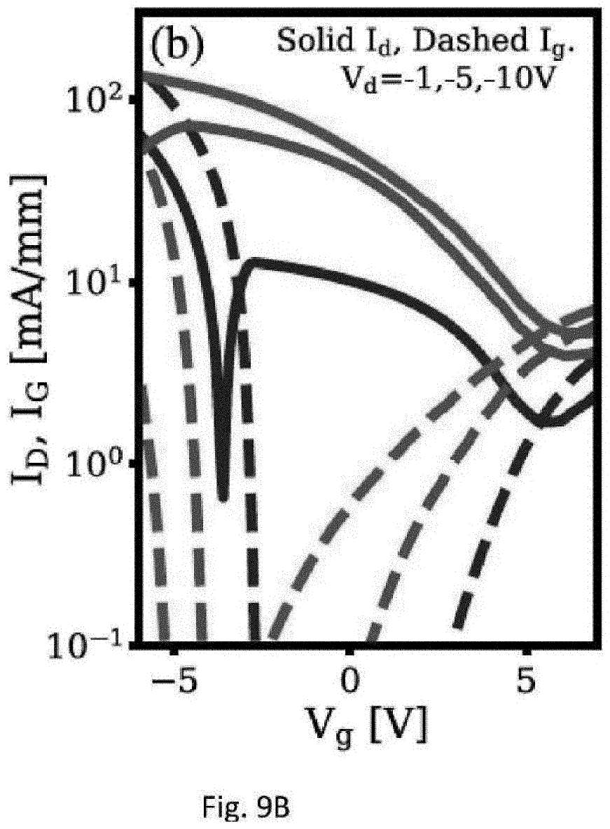

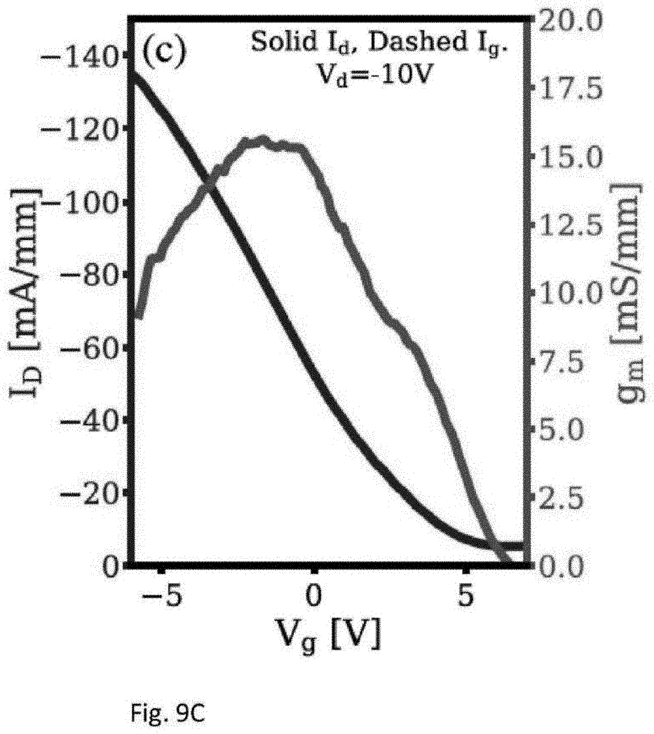

More recently, pFETs showed high current performance within a reasonable bias range, with the drain current in excess of −100 mA/mm at −10 V drain bias, shown in FIG. 9(a), an order of magnitude jump over the previous generations. For a slightly larger device, a peak transconductance of 19 mS/mm was observed with two orders of on/off modulation (FIG. 9C). This on/off ratio is limited by gate leakage. However, as this is the first-generation of Schottky-gated GaN/AlN pFET, it is likely far from optimized. Tuning of the gate placement, surface treatment, and high-K dielectric may all be incorporated to dramatically reduce leakage while retaining the overall device performance. The high 2DHG density, in combination with a p-InGaN cap layer below the ohmic contact metal (FIGS. 8A, 8C), achieve a record-low p-type contact resistance of 4.6 Ω·mm. A cross section of the device, as well as a benchmark of on-current achieved in nitride pFETs, are shown in FIGS. 8A-8E. (See Bader S J, Chaudhuri R, Hickman A, Nomoto K, Bharadwaj S, Then H W, Xing H G and Jena D 2019 Technical Digest—International Electron Devices Meeting, IEDM 2019-December 4-7; Bader S J, Lee H, Chaudhuri R, Huang S, Hickman A, Molnar A, Xing H G, Jena D, Then H W, Chowdhury N and Palacios T 2020 IEEE Transactions on Electron Devices 1-11 ISSN 0018-9383; U.S. Patent application Publication No. 2020/0144407, by Bader et al., published May 7, 2020, all of which are incorporated by reference herein in their entirety and for all purposes.)

FIGS. 8A,8B show (a) Cross-section representation and (b) SEM image of a fully processed GaN/AlN pFET of these teachings. FIGS. 8C-8D show energy band diagrams highlighting the (c) contact and (d) gated regions; Note the channel region is completely undoped. Also note that no 2D electron gas is present or shown. FIG. 8E shows a benchmark plot of III-nitride pFETs, with the highest on-currents achieved by the GaN/AlN heterostructure. The maximum reported on-current (at V_{D}=−5 V) and best-shown on/off ratio for a collection of p-channel III-Nitride devices in the literature are benchmarked together in FIG. 8E. It is readily seen that the on-currents here surpass the previously reported ones, and, the on/off ratio, without detriment to the current, can be enhanced to yield a well-positioned p-channel option.

FIG. 8A2 is an annotated expanded version of FIG. 8A. Referring to FIG. 8A2, in the instantiation shown there in, the second layer of the not intentionally doped second Group III nitride material 25 (GaN in the instantiation shown) has an indentation extending from a first surface on which the first slab of p-doped third Group III nitride material 30 (p-doped InGaN instantiation shown) and the second slab of p-doped third polar Group III nitride material 40 are disposed to a second surface disposed between the first surface and a surface in contact with the layer of a not intentionally doped AlN 105. The indentation is disposed between the first and second slabs of p-doped third Group III nitride material 30, 40. The third electrically conductive contact 80 substantially fills the indentation in the second layer of the not intentionally doped second Group III nitride material 25 (GaN in the instantiation shown). In the instance shown in FIG. 4A, the third electrically conductive contact 80 is disposed away from the first slab of p-doped third Group III nitride material 30 and the second slab of p-doped third Group III nitride material 40. First and second electrically conductive contacts are disposed on each of the first and second slabs of p-doped third Group III nitride material 30. A 2D hole gas forms at heterostructure between the not intentionally doped second Group III nitride material 25 (GaN in the instantiation shown) and the not intentionally doped AlN 105.

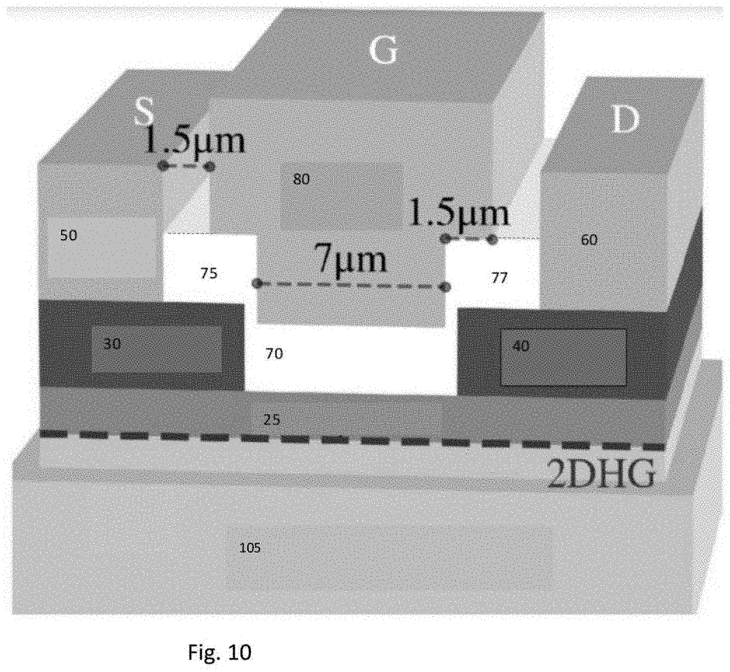

FIG. 10 show another instantiation of the Group III nitride p-FET semiconductor device. In the instantiation shown in FIG. 10, the Group III nitride semiconductor device shown there in also includes an insulating layer 70, 75, 77 disposed on a section of each one of first slab of p-doped third Group III nitride material, 30 and the second slab of p-doped third polar Group III nitride material 40 that is not covered by the first electrically conductive contact 50 and the second electrically conductive contact 60. The insulating layer 70 is also disposed on a sidewall of the first slab of p-doped third polar Group III nitride material 30 and an opposing sidewall of the second slab of p-doped third Group III nitride material 40, and disposed on the surface of the second layer of the not intentionally doped second Group III nitride material 25, the surface being located between the first slab of p-doped third Group III nitride material 30 and the second slab of p-doped third Group III nitride material 40. The third electrically conductive contact 80 is disposed over the insulating layer 70. The third electrically conductive contact is disposed away from the first and second electrically conductive contacts 50, 60.

Now that this scale of high-current performance has been demonstrated at long gate lengths (LG=0.6 μm), a roadmap of simple scaling should continue to provide several times improvement over even the current state-of-art. As the pHFET on-current approaches the same order of magnitude as the HEMT devices, it should finally become possible to match current drives (at reasonable width ratio) in III-nitrides, opening up wide-bandgap CMOS design space

Bulk Acoustic Wave (BAW) Filter Integration

RF communication systems consist of a transmit (Tx) and receive (Rx) module. The transmit module consists of a high power amplifier (PA) to create and emit high-frequency electromagnetic waves. This need is met by high-power, high-frequency transistors based on a semiconductor platform suited to the frequency and power needs. The kinds discussed earlier in this article using AlN/GaN nitride semiconductors offer a solution for the high-frequency and high-power window, in the mm-wave regime. As essential as to transmit is to be able to receive the signal to which noise has been added during transmission, and whose strength has diminished substantially by the time it is captured by an antenna. To boost the signal back, low-noise amplifiers (LNAs) are needed in the receive module. LNAs are active transistors that may be designed slightly differently from the high-power PAs to boost this regime of performance. But there is a need to first discern the frequency of the signal from the noise in several other frequencies that enter the receiver antenna. For this purpose, passive filters are used. In the mm-wave exceeding 100 GHz, substrate-integrated waveguides (SIWs) are used, which are discussed in the next section. Herein below, the filters at lower frequencies, of 10 GHz or lower, that form the front-end of receiver modules in this frequency range. Aluminum nitride plays a major role in this application because of its mix of attractive, piezoelectric and dielectric properties, are described combined with compatibility with CMOS back-end of the line (BEOL) processing restrictions. In those applications, Typically, AlN is deposited by sputtering on the Silicon platform to fabricate the filters. Increasingly, the fact that AlN is also grown epitaxially for GaN/AlN transistors is used to approach this problem from the opposite end. Hereinbelow. the opportunities in making this form of epitaxial integration of BAW with nitride electronics possible are presented.

The AlN BAW filter operates by forming a metal-insulator-metal acoustic cavity whose thickness determines the desired filter center frequency. Because of the piezoelectric property of AlN, the electromagnetic wave is converted to a sound wave of much smaller wavelength, while conserving the frequency, and thus the cavity resonator only allows those wavelengths that fit to pass through, rejecting the others. The figure of merit of this behavior is the product k²Q, where k2 is the electromechanical coupling coefficient, and Q is the quality factor of the resonator. Typical values are k2˜0.08 and Q˜5000 in the 1-10 GHz window. Since the thickness of AlN required to move to higher frequencies becomes deep sub-micron, the crystalline quality of the conventional sputtering technique poses significant challenges. The crystalline AlN used in nitride FETs and UV LEDs and Lasers have on the other hand managed to produce high quality AlN within 100 nm from the growth interfaces. Therefore, an advantage exists in using the epitaxial-AlN for fabricating BAWs. This metal electrodes have been deposited by epitaxy, realizing an all-epitaxial EpiBAW structure, in one instantiation, using NbN/AlN/NbN heterostructures (See Miller J, Wright J, Xing H G and Jena D 2020 Physica Status Solidi (A) Applications and Materials Science 217 2-7, which is incorporated by reference herein in its entirety and foe all purposes). The crystalline and piezoelectric properties of the epitaxial AlN layers have to be controlled, undesired lateral edge modes have to be avoided, and the resistance of the metal electrodes has to be controlled, which thickness should also be scaled in tandem with the thickness of the AlN layers themselves. FIGS. 1A, 1B and 1C show instantiations of an epiBAW labelled as structure (c). In FIG. 1B, structure (c) includes a first electrically conductive layer 220 under another portion of the not intentionally doped AlN buffer layer, where the first electrically conductive 220 layer is epi-deposited in a volume removed from the substrate and a second electrically conductive 240 layer disposed on another surface of the another portion of the not intentionally doped AlN buffer layer, the second electrically conductive layer 240 being opposite the first electrically conductive layer 220.

In FIG. 1A, structure (c) includes a first electrically conductive layer 220 under another portion of the not intentionally doped AlN buffer layer, where the first electrically conductive layer 220 is epi-deposited on a surface of the not intentionally doped AlN buffer layer where the surface would have been previously adjacent to the substrate, and a second electrically conductive 240 layer disposed on another surface of the another portion of the not intentionally doped AlN buffer layer, the second electrically conductive layer 240 being opposite the first electrically conductive layer 220. In one instance, the first electrically conductive layer 220 is a compound nitride metal layer. In one instantiation, the compound nitride metal layer is NbN. The second electrically conductive layer 240 can be a metal or a combination of metals, such as Ti and/or Pt. Other metals may also be used.

The more interesting opportunity afforded by the epiBAW structures is the potential to directly integrate them with the AlN/GaN/AlN HEMTs (and also the pFETs and the nitride CMOS) which are described herein above. In a certain sense, one could do a low-level of logic operation on the nitride chip before handing off the heavy signal processing to the CMOS back end in the receiver, reducing unnecessary delays and taking advantage of the direct integration afforded by the AlN platform. But for moving to the 100 GHz window, the resistive losses of the BAW are a concern since the metal electrodes should be shrunk to a few nm thickness. But integrated waveguide filters can serve as an attractive alternative, as discussed below.

AlN for Substrate Integrated Waveguides

AlN has been widely used in packaging electronic devices and circuits, including those of RF and microwave electronics. Moving up to mm-wave, the relatively high dielectric constant (k) of AlN compared to that of quartz, glasses or polymers can be turned into an advantage in reducing the interconnect size in microwave monolithically integrated circuits (MMICs), which are necessary for high-density phased arrays.

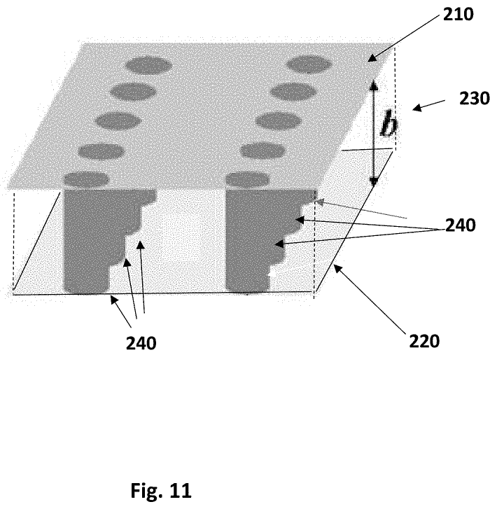

Substrate integrated waveguides (SIWs), as presently manufactured, use metallized vias to realize the edge walls (and also end walls) as shown in FIG. 11, which avoids the difficulties of manufacturing solid wall waveguide structures. (See, for example, Li Yan et al., Simulation and Experiment on SIW Slot Array Antennas, IEEE Microwave and Wireless Components Letters, VOL. 14, NO. 9, September 2004.pp. 446-448, which is incorporated by reference herein in its entirety and for all purposes.) In FIG. 11, a third conductive layer (210 in the instantiation shown, 215 in another instantiations) is disposed on one surface of the dielectric layer or layers 230 and a fourth conductive layer (220 in the instantiation shown, 225 in another instantiations) is disposed on the other surface of the dielectric layer layers 230. A number of metallized vias (240 in the instantiation shown, 245 or 247 from the other instantiations) extend from the third electrically conductive layer to the fourth electrically conductive layer. In the instantiation shown in FIG. 11, a first group from the number of vias is disposed along the first line and a second group from the number of vias is disposed along the second line, which is opposite the first line. FIG. 1A shows one instantiation in which the dielectric layers 230 includes the substrate and the AlN layer. (The structure shown in FIG. 11 has been shown in D. Deslandes et al., “Dispersion characteristics of substrate integrated rectangular waveguide,” IEEE Microwave Wireless Compon. Lett., vol. 12, pp. 333-335, September 2002, to have the same guided wave characteristics as a rectangular waveguide with equivalent width. Design rules and design considerations for a structure such as that shown in FIG. 11 are provided in Dominic Deslandes, and Ke Wu, Accurate Modeling, Wave Mechanisms, and Design Considerations of a Substrate Integrated Waveguide, IEEE Transactions on Microwave Theory and Techniques, VOL. 54, NO. 6, June 2006, pp. 2516-2526. Both of these publications are incorporated by reference herein in their entirety and for all purposes.) FIG. 1C shows another instantiation in which the dielectric layer 230 is the substrate. FIG. 1B shows still a further instantiation in which the dielectric layer is the aluminum nitride layer. (It should be noted that, although for transverse electric modes (TE modes) the cut off frequency depends only on the width, the narrow height of the AlN presents difficulties.)

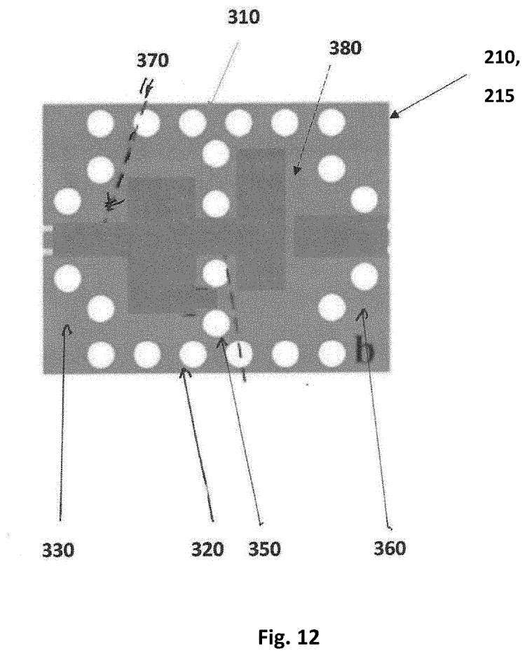

The waveguide formed by the first and second group of metallized vias and the third and fourth conductive layers, when substantially closed at each end, leaving an opening for input and output of electromagnetic radiation, forms a resonance cavity. When a second number of metallized vias is disposed between the two ends, two resonance cavities can be formed. If the second number of metallized vias leaves an opening so that the two resonance cavities can communicate, the structure can be designed to be a filter. (See, for example, Xiao-Ping Chen and Ke Wu, Substrate Integrated Waveguide Filter, IEEE Microwave Magazine, July/August 2014.pp. 108-116, and Li Y, Yang L A, Zou H, Zhang H S, Ma X H and Hao Y 2017 IEEE Electron Device Letters 38 1290-1293, both of which are incorporated by reference here in in their entirety and for all purposes.) FIG. 12 shows a top view of one instantiation of a filter using SIWs. FIG. 12, in the instantiation shown therein, shows a view from above the third electrically conductive layer (210 in one instantiation, 215 in another instantiation). A first group of metallized vias 310 from a number of metallized vias is disposed along a first line and a second group of metallized vias 320 is disposed along a second line, the first line been opposite to the second line. ⅓ group of vias 330 from the number of metallized vias extends from the first line to the second line at one end of the first line and the second line and leaves an opening for input. A fourth group of vias 360 from the number of vias extends from the first line to the second line at another end of the first line and the second line and leaves an opening for output. A second number of metallized vias 350 extends from the first group of metallized vias 310 to the second group of metallized vias 320 and is disposed between a location between the one end and the other end at the first line and a location between the one end and the other end at the second line. The second number of metallized vias 350 forms a first waveguide cavity 370 and a second waveguide cavity 360. The second number of metallized vias 350 also allows for an opening (sometimes called and iris) for electromagnetic energy communication between the first waveguide cavity 370 and the second waveguide cavity 360. The structure shown in FIG. 12 is an SIW realization of a direct coupled waveguide filter. It should be noted that structure such as FIG. 12 could be concatenated to make it more complex filter or stacked to make a more complex filter. Those instantiations are within the scope of these teachings.

TABLE 2
Properties of High-K Substrates

| | | | |
|---|---|---|---|
| Material | Sapphire Si | AlN | SiC |

| | | | | |
|---|---|---|---|---|
| Dielectric Constant | 10 | 12 | 8.9 | 9.7 |
| Loss Tangent | 10⁻⁴ | 10⁻⁴ | 10⁻⁴ | 10⁻⁴ |
| Resistivity (Ω · cm) | 10¹⁸ | <10⁵ | 10¹⁴ | >10⁵ |
| Thermal Conductivity | 0.4 | 1.3 | 3.4 | 4.2 |
| (W/cm · ° C.) | | | | |
| Temperature Coefficient | | | | |
| of Expansion (ppm/° C.) | 0.6 | 2.5 | 4.5 | 4.8 |
| Toughness(MPa · cm^{1/2}) | 13 | 8 | 45 | 46 |

Substrate-integrated waveguides (SIWs) have been developed mainly on printed circuit boards for RF and microwave electronics. Above 100 GHz, SIW can be realized on chip for mm-wave MMICs, whether the AlN layer is grown on a native substrate or on other high-k substrates such as SiC, Si or sapphire. This is because, the width of an SIW, approximately one half of the signal wavelength, is less than 1 mm above 100 GHz in high-k substrates, making the SIW small enough to be realized on chip. Although these high-k substrates have comparable dielectric constants and loss tangents (Table 2), AlN and SiC SIWs are particularly attractive for high-power nitride electronics because of their high thermal conductivities. Additionally, they have closely matched temperature coefficients of expansion for avoiding thermally induced stress in high-power electronics. Their mechanical toughness ensures high yield for SIWs made of hundreds of through-substrate vias (TSVs). Note that the TSV process is well developed for Si, AlN and SiC.

To date, most MMICs use microstrip or coplanar waveguides as interconnects, in which the current is confined along narrow metal lines. By contrast, the current is spread throughout the cross section of an SIW, resulting in higher power-handling capacity. Being well enclosed by metal TSVs and films, the SIW has negligible radiation and crosstalk, which are critical for interconnects above 100 GHz. In fact, the SIW loss is dominated by the metal conductor loss instead of radiation loss or dielectric loss. This is also why SIWs with less than 0.5 dB/mm total loss around 140 GHz has been demonstrated in high-resistivity Si and SiC, although they are not true insulators. It has also been shown that the SiC SIW is three times less lossy than microstrip or coplanar waveguides made of the same material. Lastly, with increasing frequency, the loss of the SIW decreases whereas the loss of the microstrip or coplanar waveguide increases.

Beyond low-loss and high-power interconnects, SIWs can be used as high-quality impedance transformers, filters, and antennas, which are critical components in high-power electronics but traditionally difficult to be integrated on chip. Impedance transformers can be readily realized by adding tuning TSVs in an SIW. By coupling a tuning TSV to a piezoelectrically controlled AlN varactor, tunable filters can be realized similar to that realized in quartz SIWs at the Ka band (see, for example, Asadi M J, Jin R, Ding G, Hwang J C, Scarbrough D and Goldsmith C L 2019 Journal of Microelectromechanical Systems 28 910-918, which is incorporated by reference herein in its entirety and for all purposes). SIW components can be used for antenna feeds and SIW fed end-fire antenna arrays have been demonstrated (see T. Djerafi and K. Wu Progress In Electromagnetics Research C, Vol. 26, 2012, pp. 139-151, which is incorporated by reference herein in its entirety and for all purposes).

The rapid advancements of GaN HEMTs in power and efficiency at mm-wave frequencies have enabled its prominent role in a variety of future wireless communication systems. Aluminum nitride may enhance that role via improved HEMT design and new possibilities for nitride integration. The combination of optimized GaN amplifier performance, near current-matched nitride CMOS, and state-of-the-art BAW filters and SIWs, all on the same thermally-conductive AlN platform, will bring digital logic and analog systems together on one, fully-integrated high-power chip. The AlN-enabled system can unlock new application spaces previously untouched by GaN electronics and can show the full potential of the III-nitride material system.

For the purpose of better describing and defining the present teachings, it is noted that terms of degree (e.g., “substantially,” “about,” and the like) may be used in the specification and/or in the claims. Such terms of degree are utilized herein to represent the inherent degree of uncertainty that may be attributed to any quantitative comparison, value, measurement, and/or other representation. The terms of degree may also be utilized herein to represent the degree by which a quantitative representation may vary (e.g., ±10%) from a stated reference without resulting in a change in the basic function of the subject matter at issue.

Although these teachings have been described with respect to various embodiments, it should be realized these teachings are also capable of a wide variety of further and other embodiments within the spirit and scope of the appended claims.

What is claimed is:

1. A semiconductor component comprising:
a not intentionally doped AlN buffer layer epitaxially deposited on a substrate; and
at least two structures from following structures:
(a) a second epi-layer of a second Group III nitride material epitaxially grown on the not intentionally doped AlN buffer layer;
wherein a difference between a normal component of a polarization of the second layer of the second Group III nitride material and the not intentionally doped AlN buffer layer is negative; and wherein there is an energy band offset between valence bands of the not intentionally doped AlN buffer layer and the second Group III nitride material; an energy bandgap of the second Group III nitride material being smaller than an energy bandgap of AlN; and
a 2D hole gas at a heterojunction between the not intentionally doped AlN buffer layer and the second layer of the second Group III nitride material; or
(b) a second epi-layer of a second Group III nitride material epitaxially grown on the not intentionally doped AlN buffer layer;
wherein a difference between a normal component of a polarization of the second layer of the second Group III nitride material and the not intentionally doped AlN buffer layer is negative; and wherein there is an energy band offset between valence bands of the not intentionally doped AlN buffer layer and the second Group III nitride material; an energy bandgap of the second Group III nitride material being smaller than an energy bandgap of AlN;
a 2D hole gas at a heterojunction between the not intentionally doped AlN buffer layer and the second layer of the second Group III nitride material; and
a third Group III-N barrier layer deposited over a portion of the second epi-layer of the second Group III nitride material; a thickness a of the third Group III-N barrier layer and a composition of a third Group III-N material selected such that a two dimensional electron gas (2DEG) forms at a heterojunction between the second epi-layer of the second Group III nitride material and the third Group III-N barrier layer; or
(c) a first electrically conductive layer under another portion of the not intentionally doped AlN buffer layer; the first electrically conductive layer being one of embedded epi-deposited in a volume removed from the substrate or epi-deposited on a surface of the not intentionally doped AlN buffer layer where the surface would have been previously adjacent to the substrate; and
a second electrically conductive layer disposed on another surface of the another portion of the not intentionally doped AlN buffer layer; the second electrically conductive layer being opposite the first electrically conductive layer.

2. The semiconductor component of claim 1 further comprising: an additional structure comprising:
a third electrically conductive layer disposed on a portion of the not intentionally doped AlN buffer layer;
a fourth electrically conductive layer disposed on a surface of the substrate, said surface being opposite to a surface of the substrate in which the not intentionally doped AlN buffer layer is disposed; the fourth electrically conductive layer being opposite the third electrically conductive layer; and
a plurality of metalized vias extending from the third electrically conductive layer to the fourth electrically conductive layer.

3. The semiconductor component of claim 1 further comprising: an additional structure comprising:
a third electrically conductive layer disposed on a portion of the not intentionally doped AlN buffer layer;
a fourth electrically conductive layer being one of embedded deposited in a volume removed from the substrate or deposited on a surface of the not intentionally doped AlN buffer layer where the surface would have been previously adjacent to the substrate; the third electrically conductive layer being opposite the fourth electrically conductive layer; and
a plurality of metalized vias extending from the third electrically conductive layer to the fourth electrically conductive layer.

4. The semiconductor component of claim 2 wherein a first group of the plurality of metalized vias is disposed along a first line and a second group of the plurality of metalized vias is disposed along a second line, the second line being opposite the first line.

5. The semiconductor component of claim 4 further comprising a second plurality of metalized vias extending from the first group of metalized vias to the second group of metalized vias; the second plurality of metalized vias disposed at locations between ends of the first group of metalized vias and the second group of the plurality of metalized vias.

6. The semiconductor component of claim 3 wherein a first group of the plurality of metalized vias is disposed along a first line and a second group of the plurality of metalized vias is disposed along a second line, the second line being opposite the first line.

7. The semiconductor component of claim 6 further comprising a second plurality of metalized vias extending from the first group of metalized vias to the second group of metalized vias; the second plurality of metalized vias disposed at locations between ends of the first group of metalized vias and the second group of the plurality of metalized vias.

8. The semiconductor component of claim 1 wherein structure (b) further comprises:
an n-doped fourth Group III nitride material drain region recessed into at least the second epi-layer of the second Group III nitride material, the n-doped fourth Group III nitride material drain region extending from a first end of the structure (b) to less than half a distance from the first end of the structure (b) to a second end of the structure (b);
an n-doped fourth Group III nitride material source region recessed into at least the second epi-layer of the second Group III nitride material, the-doped fourth Group III nitride material drain region extending from the second end of the structure (b) to less than half a distance from the first end of the structure (b) to a second end of the structure (b); the second epi-layer of the second Group III nitride material between the n-doped fourth Group III nitride material drain region and the n-doped fourth Group III nitride material source region forming a channel layer; and
a gate electrode disposed above the third Group III-N barrier layer and between and not in contact with the n-doped fourth Group III nitride material source region and n-doped fourth Group III nitride material drain region.

9. The semiconductor component of claim 8 wherein structure (b) also comprises a fifth Group III-N material passivation layer grown on the third Group III-N barrier layer.

10. The semiconductor component of claim 8 wherein the gate electrode includes a neck portion, the neck portion having a first width, and second portion, disposed on the first portion, and having an average width larger than the first width.

11. The semiconductor component of claim 8 wherein the second Group III nitride material is GaN, a third Group III-N material is AlN, and the fourth Group III nitride material is GaN.

12. The semiconductor component of claim 9 wherein the second Group III nitride material is GaN, a third Group III-N material is AlN, the fourth Group III nitride material is GaN, and the fifth Group III-N material is GaN.

13. The semiconductor component of claim 1 wherein structure (a) further comprises:
a first slab of p-doped third Group III nitride material disposed on the second epi-layer of the second Group III nitride material;
a second slab of p-doped third Group III nitride material disposed on the second epi-layer of the second Group III nitride material; the second slab of p-doped third polar Group III nitride material being spaced apart from the first slab of p-doped third polar Group III nitride material;
and
a first electrically conductive contact disposed over a surface of the second epi-layer of the second Group III nitride material, the surface being located between the first slab of p-doped third Group III nitride material and the second slab of p-doped third polar Group III nitride material and opposite a surface of the first layer of the not intentionally doped AlN buffer layer on which the second epi-layer of the second Group III nitride material is grown.

14. The semiconductor component of claim 13 wherein structure (a) also comprises:
a second electrically conductive contact disposed over a portion of the first slab of p-doped third polar Group III nitride material; and
a third electrically conductive contact disposed over a portion of the second slab of p-doped third polar Group III nitride material;
the first electrically conductive contact being disposed away from the third and second electrically conductive contacts.

15. The semiconductor component of claim 13 wherein the second Group III nitride material is GaN.

16. The semiconductor component of claim 13 wherein a 2D electron gas is not present. In structure (a).

17. The semiconductor component of claim 13 wherein the second Group III nitride material is InₓGa₁₋ₓN or AlₓGa₁₋ₓN where x is a number less than 1 and greater than 0.

18. The semiconductor component of claim 13 wherein the third Group III nitride material is GaN.

19. The semiconductor component of claim 13 wherein the third Group III nitride material is InₓGa₁₋ₓN where x is a number less than 1 and greater than 0.

20. The semiconductor component of claim 14 further comprising an insulating layer disposed on a section of each one of first slab of p-doped third Group III nitride material and the second slab of p-doped third Group III nitride material that is not covered by the second electrically conductive contact and the third electrically conductive contact, disposed on a sidewall of the first slab of p-doped third Group III nitride material and an opposing sidewall of the second slab of p-doped third Group III nitride material, and disposed on the surface of the second epi-layer of the second Group III nitride material, the surface being located between the first slab of p-doped third Group III nitride material and the second slab of p-doped third Group III nitride material;
the first electrically conductive contact being disposed over the insulating layer.

21. The semiconductor component of claim 1 wherein, in structure (c), the first electrically conductive layer is a compound nitride metal layer.

22. The semiconductor component of claim 21 wherein the compound nitride metal is NbN.

23. The semiconductor component of claim 1 further comprising: an additional structure comprising:
a third electrically conductive layer disposed on a portion of the substrate;
the not intentionally doped AlN buffer layer being removed from said portion of the substrate or not deposited over said portion of the substrate;
a fourth electrically conductive layer disposed on a surface of the substrate, said surface being opposite to a surface of the substrate in which the not intentionally doped AlN buffer layer is disposed; the third electrically conductive layer being opposite the fourth electrically conductive layer; and
a plurality of metalized vias extending from the third electrically conductive layer to the fourth electrically conductive layer.

24. The semiconductor component of claim 23 wherein a first group of the plurality of metalized vias is disposed along a first line and a second group of the plurality of metalized vias is disposed along a second line, the second line being opposite the first line.

25. The semiconductor component of claim 24 further comprising a second plurality of metalized vias extending from the first group of metalized vias to the second group of metalized vias; the second plurality of metalized vias disposed at location between ends of the first group of metalized vias and the second group of the plurality of metalized vias.
